(19) United States
(12) Patent Application Publication
(10) Pub. No.: US 2026/0190327 A1
(43) Pub. Date: Jul. 2, 2026

(54) MANAGING AIR GAPS IN THREE-DIMENSIONAL SEMICONDUCTOR DEVICES

(71) Applicant: Yangtze Memory Technologies Co., Ltd., Wuhan (CN)

(72) Inventors: Meng YAN, Wuhan (CN); Yijie NIE, Wuhan (CN); Ya WANG, Wuhan (CN); Zhaoyun TANG, Wuhan (CN)

(21) Appl. No.: 19/029,682

(22) Filed: Jan. 17, 2025

Related U.S. Application Data
(63) Continuation of application No. PCT/CN2025/070142, filed on Jan. 2, 2025.

(51) Int. Cl. H10B 12/00

(52) U.S. Cl. CPC H10B 12/482; H10B 12/02; H10B 12/315; H10B 12/485

(57) ABSTRACT

Systems, devices, and methods for managing air gaps in a semiconductor device are provided. In one aspect, a semiconductor device includes a first array structure including bit lines, where two adjacent bit lines are separated by a first isolation structure having a first air gap; a second array structure adjacent to the first array structure along the first direction, the second array structure including connection lines, where two adjacent connection lines are separated by a second isolation structure having a second air gap; and a gate line. A first end of the first air gap is on a first side of a first end of the second air gap, the gate line is on a second side of the first end of the second air gap.

### CROSS-REFERENCE TO RELATED APPLICATIONS

This application is a continuation of International Application No. PCT/CN 2025/070142, filed on Jan. 2, 2025, the disclosure of which is hereby incorporated by reference in its entirety.

### TECHNICAL FIELD

The present disclosure relates to semiconductor devices and fabrication processes for semiconductor devices.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing air gaps in three-dimensional (3D) semiconductor devices.

One aspect of the present disclosure features a semiconductor device, including a first array structure including bit lines, where two adjacent bit lines of the bit lines are separated by a first isolation structure along a first direction, the first isolation structure including a first air gap; a second array structure adjacent to the first array structure along the first direction, the second array structure including connection lines, where two adjacent connection lines of the connection lines are separated by a second isolation structure along the first direction, the second isolation structure including a second air gap; and a gate line extending along the first direction and adjacent to both the first array structure and the second array structure. Along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction.

In some implementations, along the second direction, the first end of the first air gap is above an end of a bit line of the two adjacent bit lines, and the first end of the second air gap is below the end of the bit line of the two adjacent bit lines.

In some implementations, an area of the second air gap is smaller than an area of the first air gap.

In some implementations, along the second direction, the second end of the first air gap is on a side of the second end of the second air gap, and the gate line is on the side of the second end of the second air gap.

In some implementations, a dimension of the second air gap along the first direction is smaller than a dimension of the first air gap along the first direction.

In some implementations, a dimension of the second air gap along the second direction is smaller than a dimension of the first air gap along the second direction.

In some implementations, the first array structure includes a semiconductor body extending along the second direction, a first end of the semiconductor body is coupled to a corresponding bit line of the bit lines, and a second end of the semiconductor body is coupled to a capacitor. The first end of the semiconductor body is opposite to the second end of the semiconductor body along the second direction.

In some implementations, the first array structure is in an array region, and the second array structure is in an edge region adjacent to the array region. The gate line includes a first portion in the array region, a third portion in the edge region, and a second portion between the first portion and the third portion along the first direction. A height of the second portion of the gate line along the second direction is greater than a height of the first portion of the gate line along the second direction.

In some implementations, the height of the first portion of the gate line along the second direction is same as a height of the third portion of the gate line along the second direction.

In some implementations, bit line contact structures arranged along the first direction in a first alternating pattern, a bit line contact structure of the bit line contact structures is coupled to a corresponding bit line of the bit lines; a plurality of gate lines including the gate line; and gate line contact structures coupled to corresponding gate lines of the plurality of gate lines and arranged along a third direction in a second alternating pattern. The third direction is perpendicular to the first direction and the second direction.

Another aspect of the present disclosure features a semiconductor device including: a first array structure including bit lines, where two adjacent bit lines of the bit lines are separated by a first isolation structure along a first direction, the first isolation structure including a first air gap; a second array structure adjacent to the first array structure along the first direction, the second array structure including connection lines, where two adjacent connection lines of the connection lines are separated by a second isolation structure along the first direction, the second isolation structure including a second air gap; and a gate line extending along the first direction and adjacent to both the first array structure and the second array structure. An area of the second air gap is smaller than an area of the first air gap.

In some implementations, along a second direction perpendicular to the first direction, a first end of the first air gap is above an end of a bit line of the two adjacent bit lines, and a first end of the second air gap is below the end of the bit line of the two adjacent bit lines.

In some implementations, along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction.

In some implementations, along the second direction, the second end of the first air gap is on a side of the second end of the second air gap, and the gate line is on the side of the second end of the second air gap.

In some implementations, a dimension of the second air gap along the first direction is smaller than a dimension of the first air gap along the first direction.

In some implementations, a dimension of the second air gap along a second direction is smaller than a dimension of the first air gap along the second direction, the second direction is perpendicular to the first direction.

Another aspect of the present disclosure features a method including: forming a first array structure including bit lines, where two adjacent bit lines of the bit lines are separated by a first isolation structure along a first direction, the first isolation structure including a first air gap; forming a second array structure adjacent to the first array structure along the first direction, the second array structure including connection lines, where two adjacent connection lines of the connection lines are separated by a second isolation structure along the first direction, the second isolation structure including a second air gap; and forming a gate line extending along the first direction and adjacent to both the first array structure and the second array structure. Along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction.

In some implementations, the method includes forming a third air gap surrounded by a first dielectric layer in the second isolation structure; removing the third air gap and the first dielectric layer in the second isolation structure; and forming the second air gap surrounded by a second dielectric layer in the second isolation structure.

In some implementations, the method includes a dimension of the third air gap is substantially equal to a dimension of the first air gap.

In some implementations, forming the second air gap surrounded by the second dielectric layer in the second isolation structure includes: depositing the second dielectric layer in the second isolation structure by atomic layer deposition (ALD).

In some implementations, the method includes depositing a conductive layer on a first initial array structure and a second initial array structure; depositing a hard mask covering a first part of the conductive layer that is on the second initial array structure; at least partially removing a second part of the conductive layer that is on the first initial array structure; and removing the hard mask.

In some implementations, the method includes depositing a conductive material on semiconductor lines of the first initial array structure; and annealing the conductive material, such that the conductive material reacts with a material of the semiconductor lines to form a composite conductive material.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIG. 2A illustrates a cross-section view of the semiconductor device of FIG. 1.

FIGS. 2B through 2E illustrate expanded views of air gaps of the semiconductor device of FIG. 2A.

FIG. 3 illustrates a plan view of the semiconductor device of FIG. 2A.

FIGS. 4A through 4J illustrate cross-section views of the semiconductor device of FIG. 2A at various stages of a manufacture process.

FIG. 5 illustrates a flow chart of an example process to form the semiconductor device of FIG. 2A.

FIG. 6 illustrates a block diagram of a system.

It is to be understood that the various exemplary implementations shown in the figures are merely illustrative representations and are not necessarily drawn to scale.

### DETAILED DESCRIPTION

In some cases, a DRAM memory device can include a memory array having a plurality of active memory cells, and the memory array can be surrounded by a dummy array structure having a plurality of dummy memory cells. The dummy array structure can include connection lines extending in the bit line direction and have a size and pitch substantially similar to that of the bit lines. In the manufacturing process, air gaps may form between adjacent connection lines of the dummy array structure. These air gaps may trap gas generated during film deposition steps, causing issues in subsequent etching process. In some cases, the outgassing can cause under-etch during contact formation when a contact hole is etched through the air gaps for reaching a structure underneath the air gap. The under-etch issue may lead to gross yield loss.

Implementations of the present disclosure provide semiconductor devices and methods for forming such semiconductor devices. In some implementations, a semiconductor device includes a first array structure including bit lines, where two adjacent bit lines of the bit lines are separated by a first isolation structure along a first direction, the first isolation structure including a first air gap; a second array structure adjacent to the first array structure along the first direction, the second array structure including connection lines, where two adjacent connection lines of the connection lines are separated by a second isolation structure along the first direction, the second isolation structure including a second air gap; and a gate line extending along the first direction and adjacent to both the first array structure and the second array structure. Along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction.

Implementations of the present disclosure can provide one or more of the following technical advantages and/or benefits. For example, the technologies described in the present disclosure can significantly improve yield by about 50% through eliminating or mitigating outgassing issue. When depositing a film (e.g., a dielectric layer) in the openings between adjacent connection lines of a dummy array structure, outgas may be generated and trapped in the air gaps between those adjacent connection lines. In some cases, the dielectric layer includes Black Diamond (BD) dielectric film and is deposited by chemical vapor deposition (CVD). The gas generated from the deposition process may subsequently cause etching issue (e.g., under-etch) when a hole is etched through the air gap for forming a conductive structure (e.g., contact) connecting to a structure underneath the air gaps (e.g., a TISO described below). The under-etch issue may lead to gross yield loss. Additionally, the air gaps may be close to a word line (e.g., in a few nanometers) along a vertical direction, leading to migration of impurities from the word line to the air gaps. These impurities may further worsen the under-etch issue. In some implementations, before the etch step, the techniques described in the present disclosure remove the outgas trapped in the air gaps and deposit a new layer of dielectric material in the openings using a different deposition method (e.g., atomic layer deposition (ALD)). In some cases, unlike CVD, ALD may not generate outgas (e.g., BDII gas), thereby eliminating or reducing the under-etch issue and improving the yield. In addition, the air gaps formed during ALD deposition process may be smaller than the air gaps formed during CVD process and may be further away from the word line. Because of increased distance between the word line and air gaps, the contamination from impurities of word lines may also be reduced, further improving the yield.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

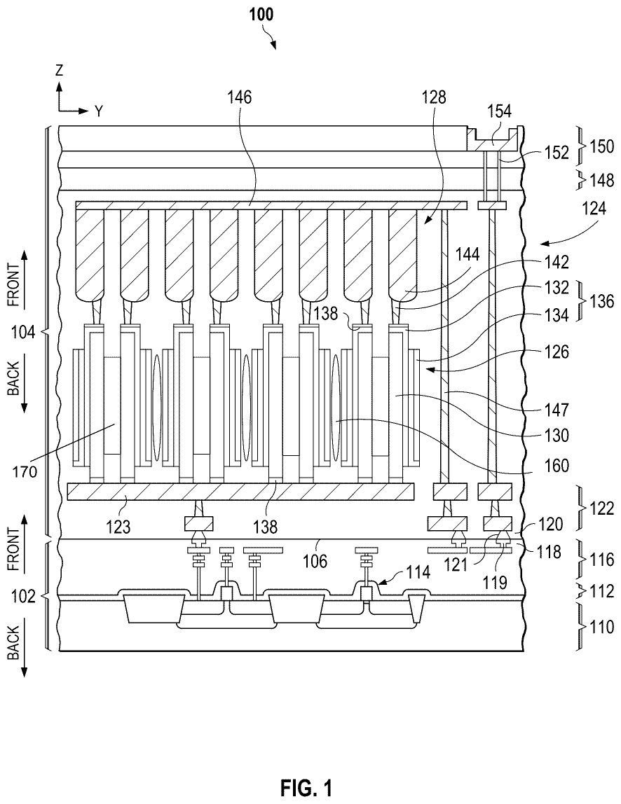

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the Y direction). In some implementations, the gate dielectric 132 abuts one side of the semiconductor body 130, and the gate electrode 134 abuts the gate dielectric 132.

As shown in FIG. 1, in some implementations, the semiconductor body 130 has two ends (the upper end and lower end in FIG. 1) in the vertical direction (the z-direction), and at least one end (e.g., the lower end) extends beyond gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the semiconductor body 130, respectively, in the vertical direction (the z-direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively small dielectric constant of air in air gaps (e.g., about ¼ of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

In some implementations, instead of the trench isolation 160 having the air gap being disposed between adjacent vertical gates 134 of two adjacent rows of the vertical transistors 126, a shielding conductive structure 170 (e.g., including metal such as W) is disposed between adjacent semiconductor bodies 130 of two adjacent rows of vertical transistors 126. The shielding conductive structure 170 can be in contact with at least one of the adjacent semiconductor bodies 130 and can be coupled to a low voltage (e.g., a fixed negative voltage), which can reduce charge build-up in the memory cells 124, thereby mitigating the floating body effect in the memory cells 124. Moreover, by applying a fixed low voltage on the shielding conductive structure 170 between the memory cells 124, a threshold voltage of the memory cells 124 can be conveniently adjusted, which can reduce the overall manufacturing complexity and cost, and improve reliability of the memory cells 124. Further, the shielding conductive structure 170 can be coupled out from a same side as word lines or a different side from the word lines. For example, the shielding conductive structure 170 can be coupled out from the back side of the second semiconductor structure 104. The shielding conductive structure 170 can be also referred as shielding conductive material. The trench isolation having such shielding conductive structure 170 may be also referred to as trench isolation (TISO) in this disclosure.

As shown in FIG. 1, in some implementations, a capacitor 128 includes a first electrode 144 above and coupled to the source or drain 138 of vertical transistor 126, e.g., the upper end of the semiconductor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 1. In some implementations, the first end of the capacitor 128 is coupled to the first terminal of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron-or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminals 138 of the vertical transistors 126) through the substrate.

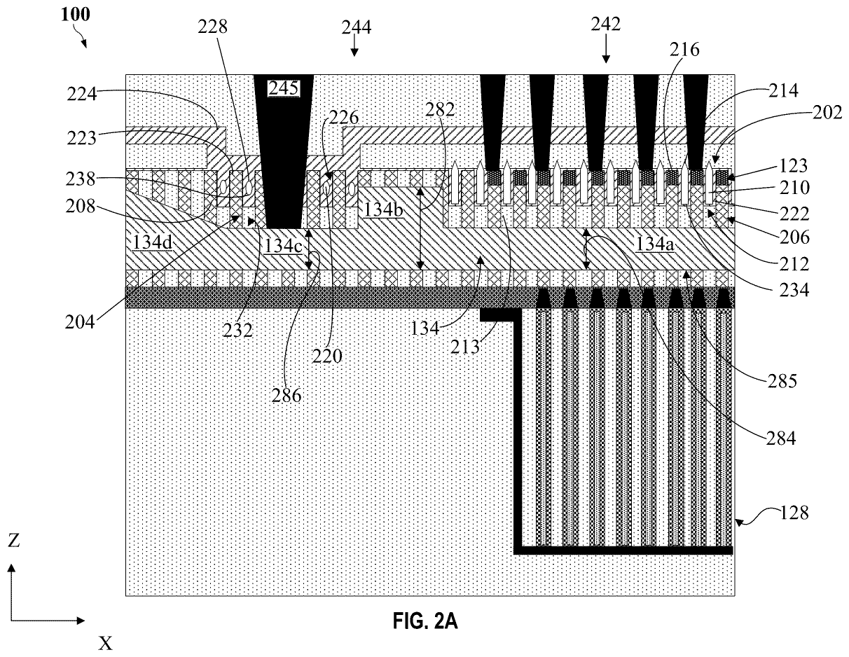

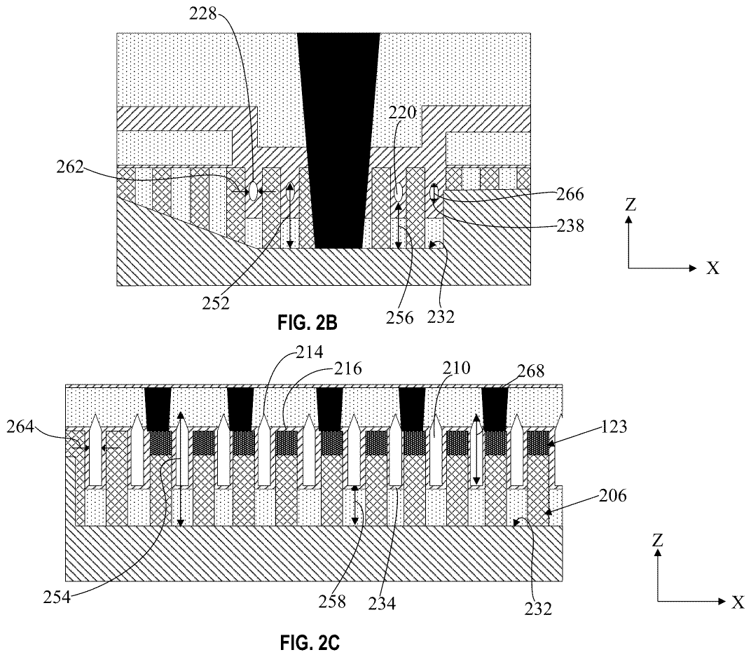

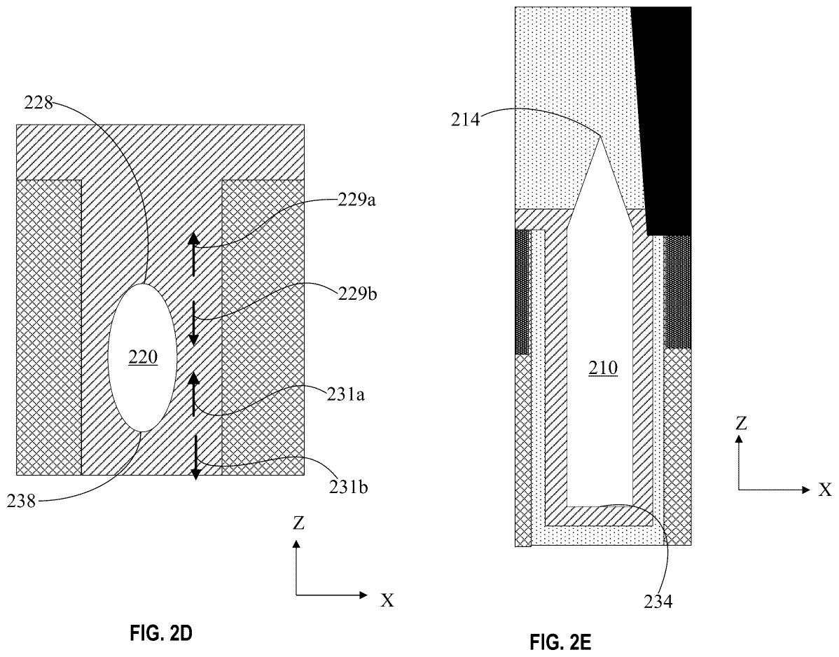

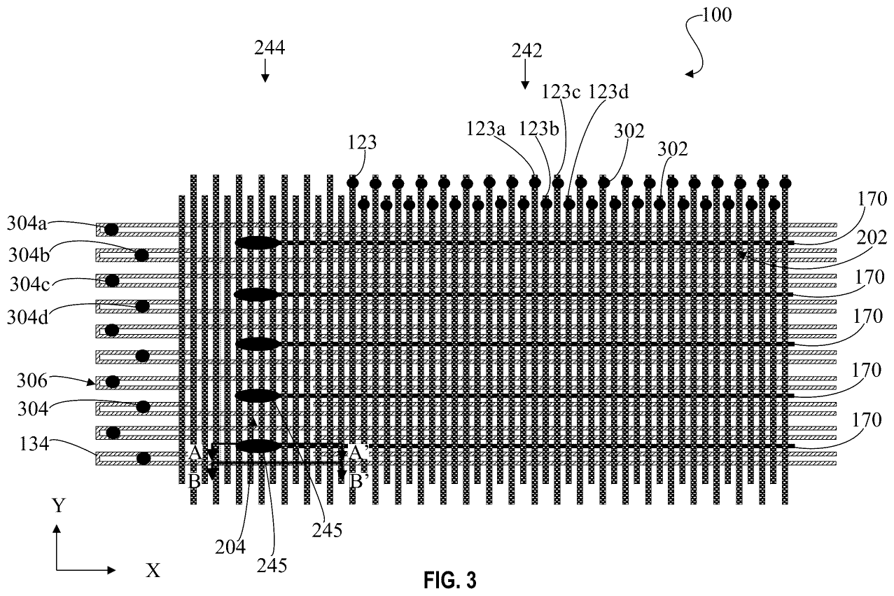

FIG. 2A illustrates a cross-section view of the semiconductor device 100 in the X-Z plane. FIGS. 2B-2E are expanded views of air gaps of the semiconductor device 100. As illustrated, the memory device 100 includes a first array structure 202 and a second array structure 204 adjacent to the first array structure 202. For ease of description, reference will be made to FIGS. 2A-2E when describing the structure of the semiconductor device 100. It is to be noted that FIGS. 2A-2E is shown from a flipped perspective along z axis compared to FIG. 1. In FIGS. 2A-2E, the bit line 123 positioned in the positive z-direction compared to capacitors 128. This contrasts with FIG. 1, where the bit line 123 is positioned in the negative z-direction of the capacitors 128. Therefore, an “upper” or a “top” end of a structure in FIG. 2A may be an “lower” end or a “bottom” end of the same structure in FIG. 1. Z direction described below in reference to FIGS. 2A-2E refers to the coordinate system used in FIGS. 2A-2E. It is to be noted that FIGS. 2A-2C can be a composite view with overlays of various cross-section planes. For example, FIG. 2A can be a composite view of cross-section planes similar to those through A-A′ axis and B-B′ axis of FIG. 3, such that FIG. 2A can illustrate both the gate line 134 and TISO contact structures 245 in a single side view. It is further to be understood that although the TISO contact structures 245 and the gate line 134 appear to be in contact with each other in FIGS. 2A and 2B due to the composite view of cross-section planes, in a real device, TISO contact structure 245 and the gate line 134 are isolated from each other. The TISO contact structure 245 can be coupled to a TISO 170 (e.g., as illustrated in FIG. 3). FIGS. 2A-2E are for illustrative purpose only and may not depict a single cross-sectional view within an actual device.

In some implementations, the first array structure 202 includes active memory cells 124 that store user data, while the second array structure 204 is a dummy array structure that does not include active memory cells 124. The second array structure 204 can be at one or more edges of the first array structure 202. In some implementations, the first array structure 202 include bit lines 123, while the second array structure 204 does not include bit lines 123. In some implementations, the first array structure 202 is coupled to capacitors 128, while the second array structure 204 does not couple to capacitors 128.

In some implementations, the first array structure 202 includes bit lines 123 extending along y direction and first semiconductor bodies 206 extending along z direction. A bit line 123 can couple to a plurality of first semiconductor bodies 206 that are arranged in a line along y direction (referring to FIG. 1). The first semiconductor bodies 206 can be, e.g., the semiconductor body 130 of FIG. 1. In some implementations, the second array structure 204 includes connection lines 223 extending along y direction and second semiconductor bodies 208 extending along z direction. A connection line 223 can couple to a plurality of second semiconductor bodies 208 that are arranged in a line along y direction. In some implementations, the connection lines 1123 include the same material (e.g., silicon) as the second semiconductor bodies 208. Unlike bit lines 123, the connection lines 223 in the second array structure 204 may not have silicide materials. Therefore, the connection lines 223 may not function as bit lines 123.

In some implementations, in a first array structure 202, two adjacent bit lines 123 of the bit lines 123 are separated by a first isolation structure 212 along a first direction (e.g., x direction in FIG. 2), and the first isolation structure 212 includes a first air gap 210. The first isolation structure 212 can refer to structure between adjacent bit lines 123. Without limiting to any particular theory, first air gaps 210 may be formed in the first isolation structure 212 due to the relatively small pitches of bit lines 123 during a film deposition process. In some implementations, the first isolation structure 212 includes a first spacer layer 222, and the first air gap 210 is surrounded by the first spacer layer 222. The first spacer layer 222 can include a low-k (low dielectric constant) dielectric material. Adjacent first semiconductor bodies 206 can be isolated by a dielectric material 213. The dielectric material 213 can be the same as or different from a material of the first spacer layer 222. In some implementations, the first spacer layer 222 includes, but without limitation to, silicon oxycarbide (SiOC), organosilicate glass (OSG), carbon-doped oxides (CDO), or Black Diamond (BD). In some implementations, the dielectric material 213 includes silicon oxide. In some implementations, the first spacer layer 222 includes BDII and is deposited by CVD.

In some implementations, in a second array structure 204, two adjacent connection lines 223 of the connection lines 223 are separated by a second isolation structure 226 along the first direction (e.g., x direction of FIG. 2A). The second isolation structure 226 can include the structure between adjacent connection lines 223. In some implementations, the second isolation structure 226 includes a second air gap 220. In some implementations, the second isolation structure 26 includes a second spacer layer 224. The second spacer layer 224 can be a dielectric layer made of dielectric materials including, but not limited to, silicon oxide, silicon nitride, silicon oxynitride, or any combination thereof. In some implementations, the second spacer layer 224 is deposited by ALD.

In some implementations, as noted above, the semiconductor device 100 further includes the gate line 134 extending along the first direction (e.g., x direction). The gate line 134 can be adjacent to both the first array structure 202 and the second array structure 204, as shown in FIGS. 1 and 2. In some implementations, the gate line is coupled to the memory cells 124 in the first array structure 202 for controlling vertical transistors 126 in memory cells 124 124, as described above in reference to FIG. 1. In some implementations, the second array structure 204 does not include active memory cells 124 or bit lines 123, and thus the gate line 134 that is adjacent to the second array structure 204 does not function as transistor gates for the second array structure 204.

In some implementations, referring to FIGS. 2A-2E, along a second direction (e.g., z direction) perpendicular to the first direction (e.g., x direction), a first end 214 of the first air gap 210 is on a first side 229a of a first end 228 of the second air gap 220 (FIGS. 2D and 2E). The gate line 134 is on a second side 229b of the first end 228 of the second air gap 220, and the second side 229b of the first end 228 of the second air gap 220 is opposite to the first side 229a of the first end 228 of the second air gap 220 along the second direction (e.g., z direction). A second end 238 of the second air gap 220 is between the first end 228 of the second air gap 220 and the gate line 134 along the second direction, and a second end 234 of the first air gap 210 is between the first end 214 of the first air gap 210 and the gate line 134 along the second direction. In other words, the first end 214 of the first air gap 210 is farther away from the capacitors 128 compared to the first end 228 of the second air gap 220 along z direction.

In some implementations, a distance 252 (referring to FIG. 2B) between a first end 228 of the second air gap 220 and an end 232 of the gate line 134 is smaller than a distance 254 (referring to FIG. 2C) between a first end 214 of the first air gap 210 and the end 232 of the gate line 134. The first end 214 of the first air gap 210 can refer to the top end of the first air gap 210 in the positive z direction that is farther away from the gate line 134 or capacitors 128. Similarly, the first end 228 of the second air gap 220 can refer to the top end of the second air gap 220 in the positive z direction that is farther away from the gate line 134 or the capacitors 128. In some implementations, the end 232 of the gate line 134 can refer to an end that is directly below the corresponding air gaps along negative z direction.

In some implementations, as shown in FIGS. 2A and 2C, the first air gap 210 extends beyond the adjacent bit lines 123. In other word, the first end 214 of the air gap 210 is above an end 216 of a bit line 123 of the two adjacent bit lines 123. The end 216 of the bit line 123 can refer to the top end of the bit line 123 that is farther away from the capacitors 128. In contrast, as shown in FIGS. 2A and 2B, the first end 228 of the second air gap 220 can be below the end 216 of the bit line 123 of the two adjacent bit lines 123.

In some implementations, an area of the second air gap 220 is smaller than an area of the first air gap 210. The area can be a cross-sectional area of the air gap in the x-z plane. X-z plane can be the plane that is perpendicular to the bit line direction (y direction). In some implementations, referring to FIGS. 2B and 2C, a dimension 262 (e.g., width) of the second air gap 220 along the word line direction (e.g., x direction) is smaller than a dimension 264 (e.g., width) of the first air gap 210 along the same direction. In some implementations, a dimension 266 (e.g., height) of the second air gap 220 along a vertical direction (e.g., z direction) is smaller than a dimension 268 (e.g., height) of the first air gap 210 along the same direction. In some implementations, a ratio of the width of the first air gap 210 to a ratio of the width of the second air gaps 220 is between 2 and 6. In some implementations, a ratio of the height of the first air gap 210 to a ratio of the height of the second air gaps 220 is between 8 and 18.

In some implementations, referring to FIGS. 2D and 2E, along the second direction (e.g., z direction), the second end 234 of the first air gap 210 is on a second side 231b of the second end 238 of the second air gap 220, and the gate line 134 is on the second side 231b of the second end 238 of the second air gap 220. The second side 231b of the second end 238 of the second air gap 220 is opposite to a first side 231a of the second end 238 of the second air gap 220 along the second direction (e.g., z direction). The first end 228 of the second air gap 220 is on the first side 231a of the second end 238 of the second air gap 220. In other words, the second end 238 of the second air gap 220 is farther away from the gate line 134 compared to the second end 234 of the first air gap 210 along positive z direction. In some implementations, referring to FIGS. 2B and 2C, a distance 256 between the second end 238 of the second air gap 220 and the end 232 of the gate line 134 is greater than a distance 258 between the second end 234 of the first air gap 210 and the end 232 of the gate line 134.

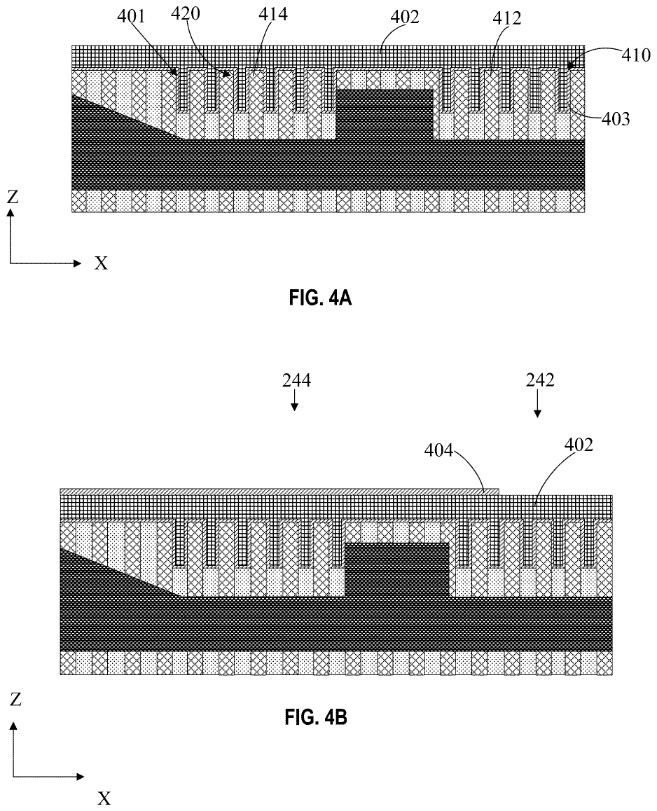

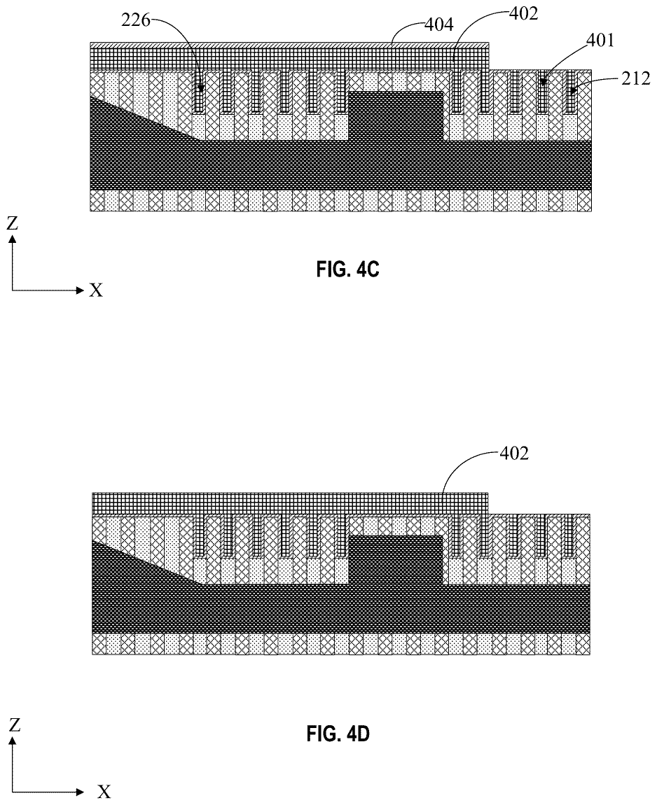

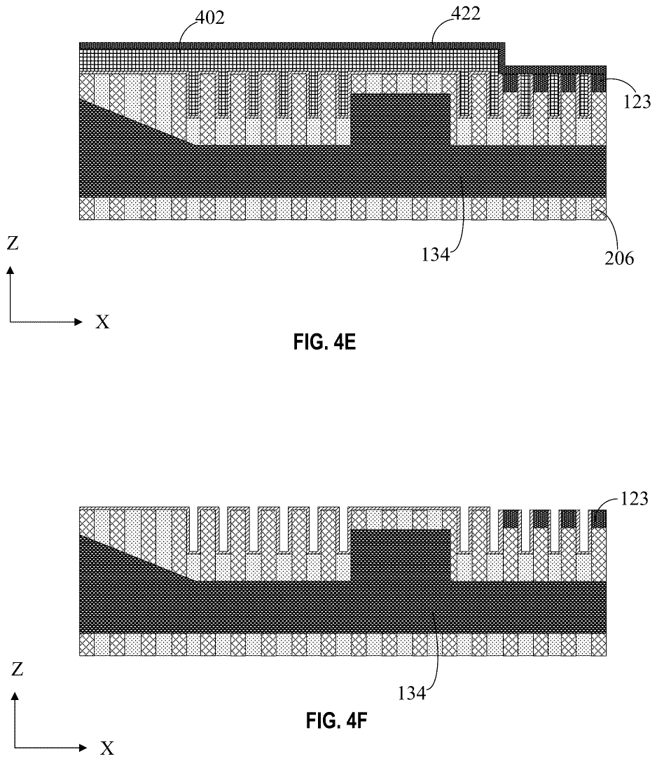

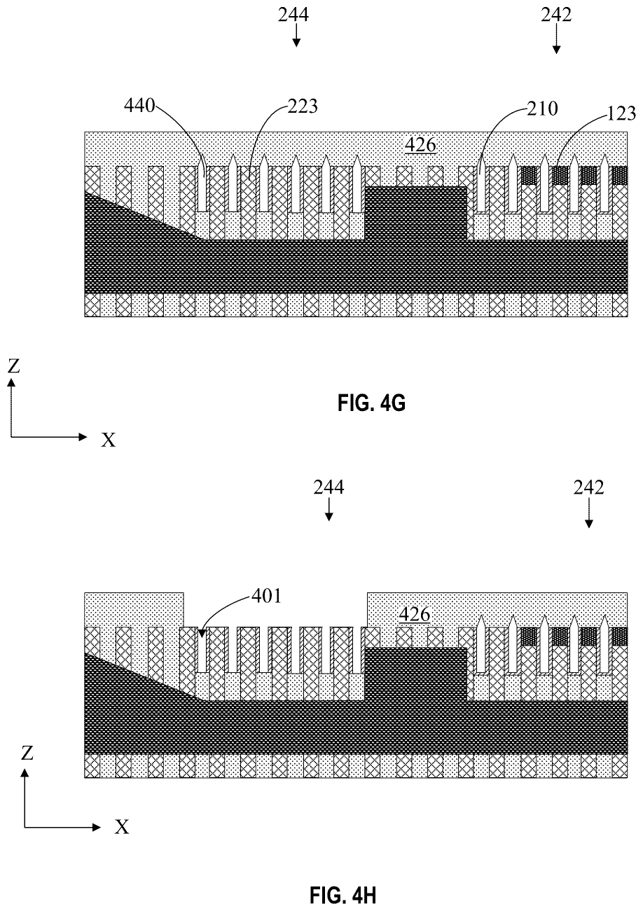

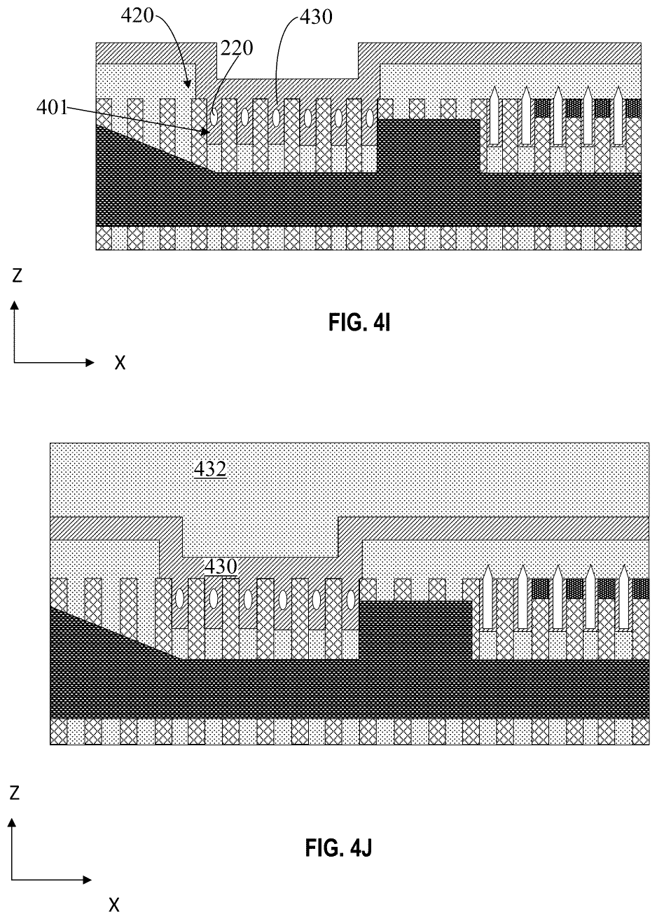

In some implementations, the second air gap 220 is formed by ALD, as discussed in further detail with reference to FIGS. 4A-4J. Without limiting to any particular theory, CVD or PVD using Black Diamond (BDII) may generate outgassing, which can be trapped in air gaps (e.g., third air gaps 440 below in FIG. 4G). These outgassing together with impurities from tungsten (W) (e.g., W in gate lines 134) can contribute to an under-etch issue when TISO contact structures 245 are formed at later stages of the process. By using ALD instead of CVD or PVD, outgassing from BDII can be eliminated or mitigated. Additionally, due to increased distance between the second air gaps 220 and the gate lines 134 along z direction, impurities from W in gate lines 134 can also be reduced. Therefore, the under-etch issue can be lessened, which in turn significantly improves manufacture yield.

In some implementations, as noted above with reference to FIGS. 1 and 2A, the first array structure 202 includes at least one first semiconductor body 206 extending along z direction. A first end (e.g., the upper end) of the semiconductor body is coupled to a corresponding bit line 123 of the bit lines 123, and a second end (e.g., the lower end) of the first semiconductor body 206 is coupled to a capacitor 128, as illustrated in FIG. 2A. The first end of the first semiconductor body 206 is opposite to the second end of the first semiconductor body 206 along z direction.

In some implementations, the first array structure 202 is in an array region 242, and the second array structure 204 is in an edge region 244 adjacent to the array region 242. The array region 242 can be defined as the region with active memory cells 124 that store user data, the region with bit lines 123, or the region with capacitors 128. The edge region 244 can be defined as the region without active memory cells 124 (e.g., only having dummy memory cells 124 that don't store user data), the region without bit lines 123, the region without capacitors 128, or the region with TISO contact structures 245.

In some implementations, the gate line 134 includes a first portion 134a in the array region 242, a third portion 134c in the edge region 244, and a second portion 134b between the first portion 134a and the third portion 134c along the first direction (e.g., x direction). A height 282 of the second portion 134b of the gate line 134 along the second direction (e.g., z direction) is greater than a height 284 of the first portion 134a of the gate line 134 along the second direction. In some implementations, the height 284 of the first portion 134a of the gate line 134 along the second direction is same as a height 286 of the third portion 134c of the gate line 134 along the second direction. Without limiting to any particular theory, a higher second portion 134b of the gate line 134 can help protect gate line 134 in the array region 242 during subsequent wet etch as illustrated in FIG. 4F below. In some implementations, the gate line 134 includes a fourth portion 134d adjacent to the third portion 134c, and the third portion 134c is between the fourth portion 134d and the second portion 134b. It is to be understood that although the fourth portion 134d of the gate line 134 shown in FIG. 2A has a slope shape, it can be in any shape, irregular or regular, in actual devices.

FIG. 3 illustrates a plan view of the semiconductor device 100 of FIG. 2A. As illustrated in FIG. 3, the semiconductor device 100 includes an array region 242 and an edge region 244. The array region 242 and the edge region 244 are adjacent to each other along the x direction. The array region 242 includes a first array structure 202. The first array structure 202 can include multiple rows of memory cells 124. Each row of memory cells 124 extends along the first direction, e.g., x direction, and can include one or more memory cells 124.

In some implementations, the semiconductor device 100 includes multiple separation regions 170. A separation region 170 is between adjacent rows of memory cells 124. The separation region 170 can be also referred as TISO 170 or shielding conductive structure 170 in the present disclosure. As described above, TISO 170 can include a shielding conductive structure (e.g., including metal such as W). The TISO 170 can be coupled to a low voltage (e.g., a fixed negative voltage), which can reduce charge build-up in the memory cell and thus mitigate the floating body effect in the memory cells 124. Moreover, by applying a fixed low voltage on the TISO 170 between the memory cells 124, a threshold voltage of the memory cells 124 can be conveniently adjusted, which can reduce the overall manufacturing complexity and cost, and improve reliability of the memory cells 124.

In some implementations, the edge region 244 of the semiconductor device 100 can include the second array structure 204 and at least one TISO contact structure 245. Each TISO contact structure 245 can be coupled to a respective TISO 170, as illustrated in FIG. 3. In some implementations, referring to FIG. 2A, the TISO contact structure 245 extends vertically into the second array structure 204. The TISO contact structure 245 can extend into one or more connection lines 223 and one or more second isolation structures 226 of the second array structure 204 along z direction to connect a corresponding TISO 170. Therefore, the TISO contact structure 245 can couple out the TISO 170 (e.g., coupling TISO 170 to a fixed negative voltage). In some implementations, the TISO contact structure 245 is made of a conductive material including, but not limited to W, Co, Cu, Al, TiN, TaN, polysilicon, or any combination thereof.

The semiconductor device 100 can include multiple bit lines 123 extending along y direction. As shown in FIG. 3, the bit lines 123 can be arranged adjacent to one another along x direction in an alternating pattern. For example, the bit lines 123 include a first bit line 123a, a second bit line 123b, a third bit line 123c, or a fourth bit line 123d. The first bit line 123a can extend beyond the adjacent second bit line 123b along y direction. Similarly, the third bit line 123c can extend beyond the fourth bit line 123d. This configuration can repeat every two bit lines 123 to form an alternating pattern or a staggered pattern. In some cases, the alternating pattern may provide larger process window for landing a bit line contact structure on a respective bit line and lower short circuit risk between adjacent bit lines, thereby improving the yield.

In some implementations, the semiconductor device 100 includes a plurality of bit line contact structures 302. A bit line contact structure 302 is coupled to a corresponding bit line 123 of the bit lines 123. The bit line contact structure 302 can land on one end of the bit line 123. Therefore, the bit line contact structures 302 can also have a first alternating pattern, similar to that of the bit lines 123 described above. The bit line contact structures 302 can electrically connect the bit line 123 to peripheral circuitries (e.g., sense amplifier) such that the peripheral circuitries can control and manage the operations of memory cells 124. In some implementations, the bit line contact structures 302 is made of a conductive material including, but not limited to W, Co, Cu, Al, TiN, TaN, polysilicon, or any combination thereof.

As shown in FIG. 3, the semiconductor device 100 can further include multiple word lines 134. The word lines 134 extend along the first direction, e.g., X direction. In some implementations, a word line 134 is coupled to transistors of at least one row of memory cells 124 for controlling the operation (e.g., read or write) of active memory cells 124 in the array region 242. As noted above, in some implementations, the edge region 244 includes dummy memory cells that do not store user data, and thus the word line 134 in the edge region 244 does not function as gates for transistors.

In some implementations, the semiconductor device 100 includes gate line contact structures 304 coupled to corresponding gate lines 134 of the plurality of gate lines 134 and arranged along a third direction (e.g., y direction) in a second alternating pattern. The gate line contact structures 304 can electrically connect the word line 134 to peripheral circuitries (e.g., word line driver) such that the peripheral circuitries can control and manage the operations of memory cells 124. Each gate line contact structure 304 can be coupled to a corresponding word line 134.

In some implementations, the gate line contact structures 304 have a second alternating pattern or a staggering pattern along y direction. For example, the gate line contact structures 304 can include a first gate line contact structure 304a, a second gate line contact structure 304b, a third gate line contact structure 304c and a fourth gate line contact structure 304d. The first gate line contact structure 304a and the third gate line contact structure 304c can be closer to an end 306 of the corresponding word line 134, while the second gate line contact structure 304b and the fourth gate line contact structure 304d can be closer to the second array structure 204. In some cases, the alternating configuration may provide larger process window for landing a gate line contact structure 304 on a respective word line 134 and lower short circuit risk between adjacent word lines 134, thereby improving the yield.

FIGS. 4A-4J illustrate cross-section views of the semiconductor device 100 at various stages of a manufacture process. It is to be understood that FIGS. 4A-4J can be a composite view with overlays of various cross-section planes. For example, FIGS. 4A-4J can be a composite view of cross-section planes similar to those through A-A′ axis and B-B′ axis of FIG. 3, such that FIGS. 4A-4J can illustrate both the gate line 134 and the semiconductor bodies 206 in a single view. Therefore, FIGS. 4A-4J are for illustrative purpose only and may not depict a single cross-sectional view within an actual device.

As illustrated in FIG. 4A, a first conductive layer 402 can be deposited on a first initial array structure 410 and a second initial array structure 420. At later process stages (e.g., as illustrated in FIG. 4I), the first initial array structure 410 can become the first array structure 202, while the second initial array structure 420 can become a second array structure 204. The first initial array structure 410 and the second initial array structure 420 can include first semiconductor lines 412 and second semiconductor lines 414 extending along y direction, respectively. The first semiconductor lines 412 of the first initial array structure 410 can become the bit lines 123 at later process stages (e.g., as illustrated in FIG. 4F), while the second semiconductor lines 414 of the second initial array structure 420 can be the connection lines 223 of FIG. 2A.

The first conductive layer 402 can fill the spacing 401 between adjacent first semiconductor lines 412 and between adjacent second semiconductor lines 414. In some implementations, before depositing the first conductive layer 402, a thin oxide layer 403 is formed on upper portions of sidewalls of the first initial array structure 410 and the second initial array structure 420, as shown in FIG. 4A. In some implementations, the first conductive layer 402 is titanium nitride (TiN) film. The first conductive layer 402 can be deposited by one or more thin film deposition processes including, but not limited to, chemical vapor deposition (CVD), physical vapor deposition (PVD), atomic layer deposition (ALD), Metal-Organic Chemical Vapor Deposition (MOCVD), sputtering, electroplating, electroless plating, electron-beam evaporation, or any combination thereof.

As illustrated in FIG. 4B, a hard mask layer 404 can be deposited on the first conductive layer 402, followed by a patterning process (e.g., photolithography and etch) to define a pattern of the hard mask layer 404. In some implementations, the hard mask layer 404 covers the edge region 244 (e.g., covering the second initial array structure 420) but exposes at least a part of the array region 242 (e.g., exposing at least a part of the first initial array structure 410).

As illustrated in FIG. 4C, the exposed part of the first conductive layer 402 (e.g., the part that is not covered by the hard mask layer 404) can be removed by etching. In some implementations, the first conductive layer 402 partially remains inside the spacing 401 between adjacent first semiconductor lines 412 after etching. The etching process can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 4D, the hard mask layer 404 can be removed by the etching techniques described above.

As illustrated in FIG. 4E, a second conductive layer 422 including a conductive material can be deposited on first semiconductor lines 412 of the first initial array structure 410. The conductive material of the second conductive layer 422 can be subsequently annealed, such that the conductive material reacts with a material (e.g., Silicon) of the first semiconductor lines 412 to form a composite conductive material. The conductive material of the second conductive layer 422 can include Ni, W, Co, Cu, or Al. The composite conductive material can be a silicide material, which includes without limitation to NiSi, WSi, CoSi, CuSi, AlSi, or any other suitable metal silicides. The composite conductive material can form the bit line 123.

As illustrated in FIG. 4F, both the first conductive layer 402 and the second conductive layer 422 can be removed. In some implementations, the removal process involves hot temperature wet etch with Sulfuric Peroxide Mixture (SPM). In some implementations, another annealing process is performed after removing the first conductive layer 402 and the second conductive layer 422.

As illustrated in FIG. 4G, a first dielectric layer 426 can be deposited in both array region 242 and edge region 244. The first dielectric layer 426 can be, e.g., the first spacer layer 222 of FIGS. 2A-2E. In some implementations, during deposition, one or more first air gaps 210 are formed in the array region 242, and one or more third air gaps 440 are formed in the edge region 244. In some implementations, a dimension of the third air gap 440 is same as or substantially similar to a dimension of the first air gap 210. For example, as illustrated in FIG. 4G, the first air gaps 210 and the third air gaps 440 can have substantially similar width along x direction, and/or substantially similar height along z direction. Without limiting to any particular theory, air gaps may be formed during thin film deposition process due to the relatively small pitches between adjacent bit lines 123 or connection lines 223. In some implementations, the first dielectric layer 426 can include, but not limited to, Black Diamond (BD), silicon oxycarbide (SiOC), organosilicate glass (OSG), carbon-doped oxides (CDO), silicon oxide, silicon nitride, silicon oxynitride, or any combination thereof. The first dielectric layer 426 can be deposited using one or more thin film deposition techniques, including, but not limited to, chemical vapor deposition (CVD), physical vapor deposition (PVD), plasma-enhanced chemical vapor deposition (PECVD), sputtering, or any combination thereof.

As illustrated in FIG. 4H, the first dielectric layer 426 can be patterned, e.g., a portion of the first dielectric layer 426 can be removed in the edge region 244. During this process, the third air gaps 440 can be removed in the spacing 401 between adjacent connection lines 223. The third air gaps 440 in the edge region 244 can be removed by a plurality of processes including, but not limited to, photolithography, dry/wet etch, and any other suitable processes.

As illustrated in FIG. 4I, a second dielectric layer 430 can be deposited. The second dielectric layer 430 can be, e.g., the second spacer layer 224 of FIGS. 2A-2E. The second dielectric layer 430 can partially fill into the spacing 401 such that the second air gaps 220 can be formed surrounded by the second dielectric layer 430. In some implementations, the second dielectric layer 430 is formed by atomic layer deposition (ALD). Without limiting to any particular theory, compared to other deposition methods (e.g., CVD, PVD), ALD has better precision in controlling the thickness of the deposited film and can deposit more uniform films on substrates with complex geometries, e.g., structures with narrow pitches or high aspect ratios. Here, by employing ALD to deposit the second dielectric layer 430, better step coverage can be achieved in the second initial array structure 420 that has a high aspect ratio. As a result, more dielectric material can be deposited into the spacing 401, reducing the size of air gaps (e.g., comparing the third air gaps 440 to the second air gaps 220). In some implementations, the second dielectric layer 430 includes silicon oxide, silicon nitride, silicon oxynitride, or any combination thereof.

As noted above, without limiting to any particular theory, CVD or PVD using Black Diamond (BDII) may generate outgassing, which can be trapped in air gaps (e.g., third air gaps 440 in FIG. 4G). These outgassing together with impurities from W (e.g., W in gate lines 134) can contribute to an under etch issue when TISO contact structures 245 are formed at later stages of the process. By removing the third air gaps 440 and subsequently forming the second air gaps 220 using ALD instead of CVD or PVD, outgassing from BDII can be eliminated or mitigated. Additionally, due to increased distance between the second air gaps 220 and the gate lines 134 along z direction, impurities from W in gate lines 134 can also be reduced. Therefore, the under-etch issue can be lessened, which in turn improves manufacture yield.

As illustrated in FIG. 4J, a third dielectric layer 432 can be deposited on the second dielectric layer 430. The third dielectric layer 432 can include silicon oxide, silicon nitride, silicon oxynitride, or any combination thereof. In some implementations, the third dielectric layer 432 includes Tetraethyl Orthosilicate (TEOS). It is to be understood that in actual devices, the interface between the second dielectric layer 430 and the third dielectric layer 432 may not be visible through certain imaging technique (e.g., Transmission Electron Microscopy), but may be visible through other imaging techniques (e.g., staining)

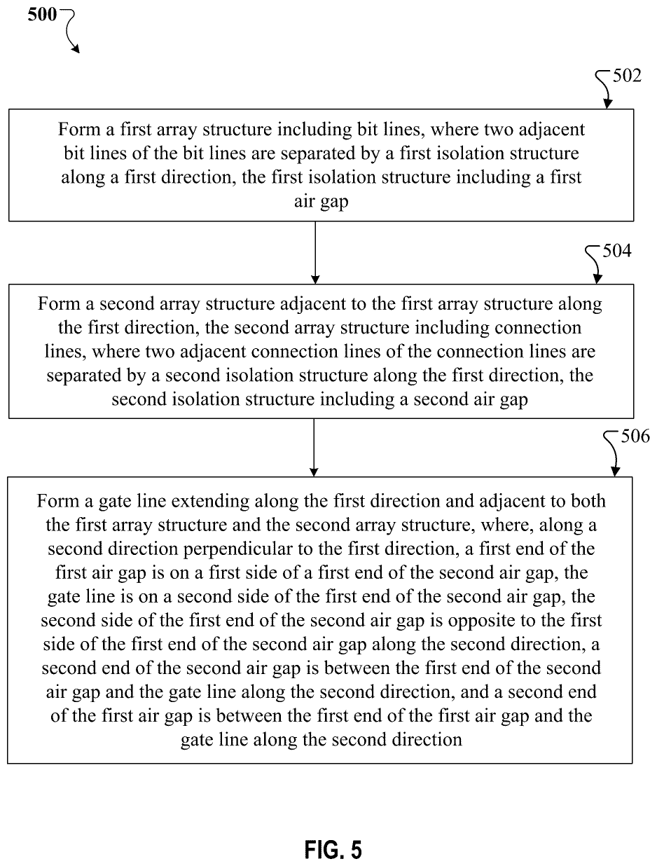

FIG. 5 illustrates a flow chart of an example process to form a semiconductor device. The semiconductor device can be, e.g., the semiconductor device 100 of FIGS. 1-4J.

At step 502, a first array structure is formed which includes bit lines. Two adjacent bit lines of the bit lines are separated by a first isolation structure along a first direction. The first isolation structure includes a first air gap. The first array structure can be, e.g., the first array structure 202 of FIGS. 2A-2C, 3 and 4G-4J. The bit lines can be, e.g., the bit lines 123 of FIGS. 1-3 and FIGS. 4E-4J. The first isolation structure can be, e.g., the first isolation structure 212 of FIGS. 2A-2E and 4G-4J. The first direction can be, e.g., the x direction or word line direction of FIGS. 2A-4J.

At step 504, a second array structure is formed adjacent to the first array structure along the first direction. The second array structure includes connection lines. Two adjacent connection lines of the connection lines are separated by a second isolation structure along the first direction, the second isolation structure comprising a second air gap. The second array structure can be, e.g., the second array structure 204 of FIGS. 2A-2C, 3, 4I and 4J. The connection lines can be, e.g., the connection lines 223 of FIGS. 2A-3, or the second semiconductor lines 414 of FIGS. 4A-4J. The second isolation structure can be, e.g., the second isolation structure 226 of FIGS. 2A-2E and 4I-4J. The second air gap can be, e.g., the second air gap 220 of FIGS. 2A-2E, 4I and 4J.

At step 506, a gate line is formed, which extends along the first direction and adjacent to both the first array structure and the second array structure. Along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction. The gate line can be, e.g., the gate line 134 of FIGS. 1-4J. The first end of the first air gap can be, e.g., the first end 214 of the first air gap 210 of FIGS. 2A-2E. The first side of the first end of the second air gap can be, e.g., the first side 229a of the first end 228 of the second air gap 220 of FIGS. 2A-2E. The second side of the first end of the second air gap can be, e.g., the second side 229b of the first end 228 of the second air gap 220 of FIGS. 2A-2E. A second end of the second air gap can be, e.g., the second end 238 of the second air gap 220 of FIGS. 2A-2E. The second end of the first air gap can be, e.g., the second end 234 of the first air gap 210 of FIGS. 2A-2E.

In some implementations, the process includes forming a third air gap surrounded by a first dielectric layer in the second isolation structure; removing the third air gap and the first dielectric layer in the second isolation structure; and forming the second air gap surrounded by a second dielectric layer in the second isolation structure. The third air gaps can be, e.g., the third air gaps 440 of FIG. 4G. The first dielectric layer can be, e.g., the first spacer layer 222 of FIGS. 2A-2E, or the first dielectric layer 426 of FIG. 4G. The second dielectric layer can be, e.g., the second spacer layer 224 of FIGS. 2A-2E, or the second dielectric layer 430 of FIGS. 4I and 4J.

In some implementations, a dimension (e.g., width, height, area) of the third air gap is substantially equal to a dimension (e.g., width, height, area) of the first air gap.

In some implementations, forming the second air gap surrounded by the second dielectric layer in the second isolation structure includes: depositing the second dielectric layer in the second isolation structure by atomic layer deposition (ALD).

In some implementations, the process includes depositing a conductive layer on a first initial array structure and a second initial array structure; depositing a hard mask covering a first part of the conductive layer that is on the second initial array structure; at least partially removing a second part of the conductive layer that is on the first initial array structure; and removing the hard mask, as described above in reference to FIGS. 4A-4D.

In some implementations, the process includes depositing a conductive material on semiconductor lines of the first initial array structure; and annealing the conductive material, such that the conductive material reacts with a material of the semiconductor lines to form a composite conductive material, as described above in reference to FIG. 4E.

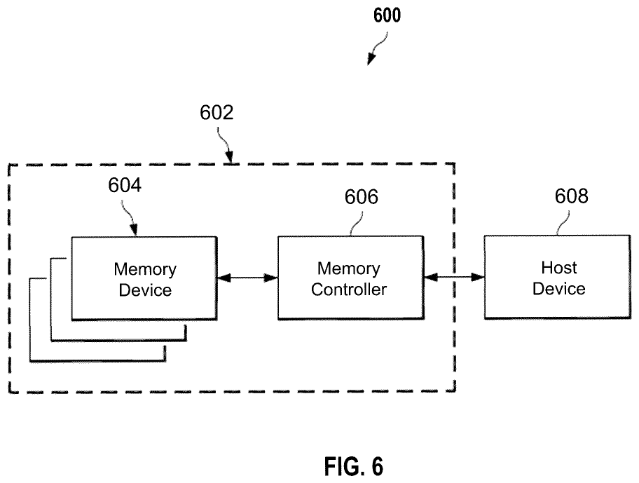

FIG. 6 illustrates a block diagram of a system 600 having one or more semiconductor device 100s (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIG. 1, or a part of the 3D semiconductor device 100 (e.g., FIGS. 2A-3), or a structure at an intermediate fabrication process of the 3D semiconductor device 100 of FIG. 1 (e.g., FIGS. 4A-4J).

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first array structure comprising bit lines, wherein two adjacent bit lines of the bit lines are separated by a first isolation structure along a first direction, the first isolation structure comprising a first air gap;
a second array structure adjacent to the first array structure along the first direction, the second array structure comprising connection lines, wherein two adjacent connection lines of the connection lines are separated by a second isolation structure along the first direction, the second isolation structure comprising a second air gap; and
a gate line extending along the first direction and adjacent to both the first array structure and the second array structure,
wherein, along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction.

2. The semiconductor device of claim 1, wherein, along the second direction, the first end of the first air gap is above an end of a bit line of the two adjacent bit lines, and the first end of the second air gap is below the end of the bit line of the two adjacent bit lines.

3. The semiconductor device of claim 1, wherein an area of the second air gap is smaller than an area of the first air gap.

4. The semiconductor device of claim 1, wherein along the second direction, the second end of the first air gap is on a side of the second end of the second air gap, and the gate line is on the side of the second end of the second air gap.

5. The semiconductor device of claim 1, wherein a dimension of the second air gap along the first direction is smaller than a dimension of the first air gap along the first direction.

6. The semiconductor device of claim 1, wherein a dimension of the second air gap along the second direction is smaller than a dimension of the first air gap along the second direction.

7. The semiconductor device of claim 1, wherein the first array structure comprises a semiconductor body extending along the second direction, a first end of the semiconductor body is coupled to a corresponding bit line of the bit lines, and a second end of the semiconductor body is coupled to a capacitor, the first end of the semiconductor body being opposite to the second end of the semiconductor body along the second direction.

8. The semiconductor device of claim 1, wherein the first array structure is in an array region, and the second array structure is in an edge region adjacent to the array region,
wherein the gate line comprises a first portion in the array region, a third portion in the edge region, and a second portion between the first portion and the third portion along the first direction, and
wherein a height of the second portion of the gate line along the second direction is greater than a height of the first portion of the gate line along the second direction.

9. The semiconductor device of claim 8, wherein the height of the first portion of the gate line along the second direction is same as a height of the third portion of the gate line along the second direction.

10. The semiconductor device of claim 1, comprising:
bit line contact structures arranged along the first direction in a first alternating pattern, a bit line contact structure of the bit line contact structures being coupled to a corresponding bit line of the bit lines;
a plurality of gate lines including the gate line; and
gate line contact structures coupled to corresponding gate lines of the plurality of gate lines and arranged along a third direction in a second alternating pattern, the third direction being perpendicular to the first direction and the second direction.

11. A semiconductor device, comprising:
a first array structure comprising bit lines, wherein two adjacent bit lines of the bit lines are separated by a first isolation structure along a first direction, the first isolation structure comprising a first air gap;
a second array structure adjacent to the first array structure along the first direction, the second array structure comprising connection lines, wherein two adjacent connection lines of the connection lines are separated by a second isolation structure along the first direction, the second isolation structure comprising a second air gap; and
a gate line extending along the first direction and adjacent to both the first array structure and the second array structure,
wherein an area of the second air gap is smaller than an area of the first air gap.

12. The semiconductor device of claim 11, wherein, along a second direction perpendicular to the first direction, a first end of the first air gap is above an end of a bit line of the two adjacent bit lines, and a first end of the second air gap is below the end of the bit line of the two adjacent bit lines.

13. The semiconductor device of claim 11, wherein, along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction.

14. The semiconductor device of claim 13, wherein along the second direction, the second end of the first air gap is on a side of the second end of the second air gap, and the gate line is on the side of the second end of the second air gap.

15. The semiconductor device of claim 11, wherein a dimension of the second air gap along the first direction is smaller than a dimension of the first air gap along the first direction.

16. The semiconductor device of claim 11, wherein a dimension of the second air gap along a second direction is smaller than a dimension of the first air gap along the second direction, the second direction being perpendicular to the first direction.

17. A method, comprising:
forming a first array structure comprising bit lines, wherein two adjacent bit lines of the bit lines are separated by a first isolation structure along a first direction, the first isolation structure comprising a first air gap;
forming a second array structure adjacent to the first array structure along the first direction, the second array structure comprising connection lines, wherein two adjacent connection lines of the connection lines are separated by a second isolation structure along the first direction, the second isolation structure comprising a second air gap; and
forming a gate line extending along the first direction and adjacent to both the first array structure and the second array structure,
wherein, along a second direction perpendicular to the first direction, a first end of the first air gap is on a first side of a first end of the second air gap, the gate line is on a second side of the first end of the second air gap, the second side of the first end of the second air gap is opposite to the first side of the first end of the second air gap along the second direction, a second end of the second air gap is between the first end of the second air gap and the gate line along the second direction, and a second end of the first air gap is between the first end of the first air gap and the gate line along the second direction.

18. The method of claim 17, comprising:
forming a third air gap surrounded by a first dielectric layer in the second isolation structure;
removing the third air gap and the first dielectric layer in the second isolation structure; and
forming the second air gap surrounded by a second dielectric layer in the second isolation structure.

19. The method of claim 18, wherein forming the second air gap surrounded by the second dielectric layer in the second isolation structure comprises:
depositing the second dielectric layer in the second isolation structure by atomic layer deposition (ALD).

20. The method of claim 17, comprising:
depositing a conductive layer on a first initial array structure and a second initial array structure;
depositing a hard mask covering a first part of the conductive layer that is on the second initial array structure;
at least partially removing a second part of the conductive layer that is on the first initial array structure; and
removing the hard mask.
